(19) United States
(12) Patent Application Publication
(10) Pub. No.: US 2026/0301679 A1
(43) Pub. Date: Oct. 1, 2026

(54) DISPLAY DEVICES

(71) Applicants: Wuhan China Star Optoelectronics Semiconductor Display Technology Co., Ltd., Wuhan (CN); Wuhan China Star Optoelectronics Technology Co., Ltd., Wuhan (CN)

(72) Inventor: Huanxi ZHANG, Wuhan, Hubei (CN)

(73) Assignees: Wuhan China Star Optoelectronics Semiconductor Display Technology Co., Ltd., Wuhan (CN); Wuhan China Star Optoelectronics Technology Co., Ltd., Wuhan (CN)

(21) Appl. No.: 19/374,199

(22) Filed: Oct. 30, 2025

Related U.S. Application Data
(63) Continuation of application No. PCT/CN2025/096997, filed on May 23, 2025.

(30) Foreign Application Priority Data
Mar. 31, 2025 (CN) 202510398009.0

(51) Int. Cl. G09G 3/3266; G11C 19/28

(52) U.S. Cl. CPC G09G 3/3266; G09G 2310/0286; G09G 2310/08; G09G 2320/0233; G11C 19/28

(57) ABSTRACT

A display device includes a display panel, and the display panel includes first gate driver on array (GOA) and second GOA each including a plurality of gate drive subcircuits that are cascaded. In a first example, the signal transmitted by node P in the i-th stage gate drive subcircuit of the first GOA has a pulse width of 2j horizontal scan time units and the signal transmitted by node P in the i-th stage gate drive subcircuit of the second GOA has a pulse width greater than 2j horizontal scan time units, where each of i and j is a positive integer. In a second example, the i-th stage gate drive subcircuit includes a gate drive signal output module, and a control module for enabling the gate drive signal to receive an active signal during a time period when no active signal is originally input.

### RELATED APPLICATIONS

This application is a Continuation of PCT Patent Application No. PCT/CN2025/096997, filed on May 23, 2025, which claims the benefit of priority of Chinese Patent Application No. 202510398009.0 filed on Mar. 31, 2025. The contents of the above applications are all incorporated by reference as if fully set forth herein in their entirety.

### TECHNICAL FIELD

The present application relates to display technologies, and in particular to display devices

### BACKGROUND

CMOS (Complementary Metal-Oxide-Semiconductor) GOA (Gate driver On Array) technology can implement zone-based frequency division in a display panel and output multiple gate drive signals.

In the display panel employing the CMOS GOA technology, one of the multiple gate drive signals output by the GOA remains in a high level hold state. This gate drive signal in the high level hold state has no active signal input.

In the drive circuit for the pixel of the aforementioned display panel, the input terminal of the one of the multiple gate drive signals output by the GOA is relatively close to the input terminals of other gate drive signals, thus impurity particles within production line may cause a slight short circuit between them, with short-circuit resistance ranging from 0.1 MΩ (megaohm) to 5 MΩ. This slight short circuit can cause mutual interference between different gate drive signals. Particularly when being in the high level hold state, the one of the multiple gate drive signals becomes more susceptible to low-level signals from the input terminals of the other gate drive signals. For example, the potential of the one of the multiple gate drive signals is pulled low, thereby affecting the normal display of the display panel and causing a loss in the yield of the display panel.

### SUMMARY

According to some embodiments of the present application, a display device includes a display panel. The display panel includes: a first GOA disposed on a first side of a display area of the display panel; and a second GOA disposed on a second side of the display area. Each of the first GOA and the second GOA includes a plurality of gate drive subcircuits that are cascaded, and an i-th stage gate drive subcircuit of the gate drive subcircuits includes a first frequency-division control module and a first gate drive signal output module, where i is a positive integer. The first gate drive signal output module includes a sixth transistor and an eighth transistor, a gate of the eighth transistor is electrically connected to a node P_(i−j) in an (i−j)-th stage gate drive subcircuit of the gate drive subcircuits, one of a source and drain of the eighth transistor is electrically connected to a node M_i and another of the source and drain of the eighth transistor is electrically connected to a node Q1_i, where the node Q1_i is a node on a line between the sixth transistor and the eighth transistor, the node M_i is a node on a line between the first frequency-division control module and the first gate drive signal output module, and the node P_(i−j) is a node on a line between a first frequency-division control module and a first gate drive signal output module within the (i−j)-th stage gate drive subcircuit, where j is a positive integer. A signal transmitted by the node M_i in the i-th stage gate drive subcircuit of the first GOA is inverse to a signal transmitted by a node P_i in the i-th stage gate drive subcircuit of the first GOA; a pulse width of the signal transmitted by the node P_i in the i-th stage gate drive subcircuit of the first GOA is 2j horizontal scan time units, and a pulse width of a signal transmitted by the node P_i in the i-th stage gate drive subcircuit of the second GOA is greater than 2j horizontal scan time units, where the node P_i is a node on another line between the first frequency-division control module and the first gate drive signal output module in the i-th stage gate drive subcircuit.

According to some embodiments of the present application, a display device includes a display panel. The display panel includes: a GOA disposed on at least one side of a display area of the display panel and including a plurality of gate drive subcircuits that are cascaded, where an i-th stage gate drive subcircuit of the gate drive subcircuits includes a self-stabilizing module, a first frequency-division control module, a first gate drive signal output module and a control module, where i is a positive integer. The first gate drive signal output module includes a seventh transistor, a gate of the seventh transistor is electrically connected to a node N_i, one of a source and drain of the seventh transistor is electrically connected to a first high-level signal input terminal and another of the source and drain of the seventh transistor is electrically connected to a first gate drive signal output terminal, where the node N_i is a node on a line between the control module and the first gate drive signal output module. The control module includes a twenty-sixth transistor and a twenty-seventh transistor, a gate of the twenty-sixth transistor is electrically connected to a node P_i, one of a source and drain of the twenty-sixth transistor is electrically connected to the node P_i, another of the source and drain of the twenty-sixth transistor is electrically connected to a node N_i, a gate of the twenty-seventh transistor is electrically connected to a node K_i, one of a source and drain of the twenty-seventh transistor is electrically connected to the node N_i and another of the source and drain of the twenty-seventh transistor is electrically connected to a node O_(i−k), where the node K_i is a node on a line between the self-stabilizing module and the first frequency-division control module of the i-th stage gate drive subcircuit, the node P_i is a node on another line between the self-stabilizing module and the first frequency-division control module of the i-th stage gate drive subcircuit and the node O_(i−k) is a node on a line between a twelfth transistor and a thirteenth transistor in the self-stabilizing module of an (i−k)-th stage gate drive subcircuit of the gate drive subcircuits, where k is a positive integer.

### BRIEF DESCRIPTION OF THE DRAWINGS

FIG. 1 is a schematic diagram of a display device according to some embodiments of the present application.

FIG. 2 is a schematic diagram of a display panel with a gate drive subcircuit employing a one-to-one drive mode in the display device as shown in FIG. 1.

FIG. 3 is a schematic diagram of a display panel with a gate drive subcircuit employing a one-to-two drive mode in the display device as shown in FIG. 1.

FIG. 4 is a circuit diagram of a pixel in the display device according to some embodiments of the present application.

FIG. 5 is a circuit diagram of a gate drive subcircuit of a display device according to a first example of the present application.

FIG. 6 illustrates waveforms of start signals and gate drive signals for the display device according to the first example of the present application.

FIG. 7 illustrates waveforms of signals at respective nodes in a first GOA and a second GOA of the display device under different pulse width settings according to the first example of the present application.

FIG. 8 schematically illustrates a horizontal region, with no active signal input, existing on the right side of an under-screen camera opening area of a display panel in the display device according to the first example of the present application.

FIG. 9 illustrates waveforms showing variations of signal waveforms at a first gate drive signal input terminal, under different impedances, of a pixel in the horizontal region with no active signal input as shown in FIG. 8 and variations of a potential at node X of that pixel.

FIG. 10 illustrates waveforms showing variations of signal waveforms at a first gate drive signal input terminal, under different impedances, of a pixel in other regions of the display panel as shown in FIG. 8 and variations of a potential at node X of that pixel.

FIG. 11 is a circuit diagram of a gate drive subcircuit of a display device according to a second example of the present application.

FIG. 12 illustrates waveforms of signals at respective nodes of a gate drive subcircuit of a display device before improvement according to some embodiments of the present application.

FIG. 13 illustrates waveforms of signals at respective nodes of an improved gate drive subcircuit of a display device according to some embodiments of the present application.

### DETAILED DESCRIPTION

Some embodiments of the present application will be described in detail below with reference to the accompanying drawings. The embodiments are described for illustrative purposes only and are not intended to limit the present application.

The terms “first”, “second” and the like do not indicate any order, quantity or importance, but are used merely to distinguish different technical features.

The display device according to embodiments of the present application may be, for example, an organic light-emitting diode (OLED) display device, a mini light-emitting diode (Mini-LED) display device or a micro light-emitting diode (Micro-LED) display device. The embodiments of the present application are described using an OLED display device.

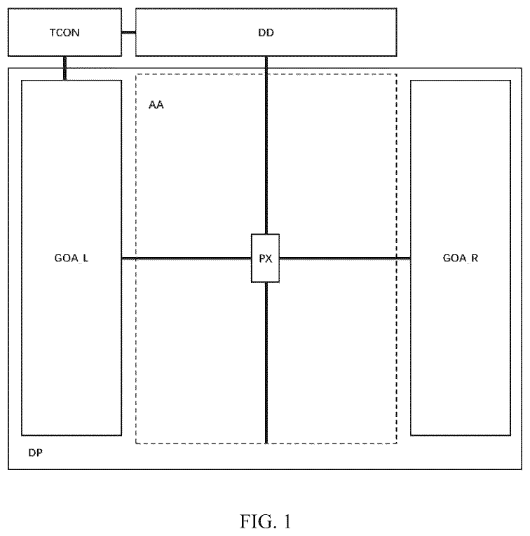

In FIG. 1, the display device according to some embodiments of the present application includes a display panel DP, a timing controller TCON, a source drive circuit DD and a power management chip (not shown in the figure, and the power management chip may be integrated with the timing controller TCON into a single chip). The display panel DP is an OLED display panel and includes GOAs (GOA_L, GOA_R) and multiple pixels PX. The GOA (GOA_L, GOA_R) includes multiple gate drive subcircuits that are cascaded, with each gate drive subcircuits being electrically connected to at least one row of pixels PX.

The display panel DP includes a display area AA and a non-display area. The display area AA is provided with m×n pixels PX arranged in an array, where m and n are integers greater than 1. The non-display area is located around the display area AA and is used for arranging drive circuits and various signal lines. The display panel DP further includes multiple scanning lines (Nscan1, Pscan1, Nscan2, Pscan2), multiple data lines DATA, and the GOAs (GOA_L, GOA_R). The multiple scanning lines extend along a first direction and are arranged along a second direction, while the multiple data lines DATA extend along the second direction and are arranged along the first direction, with the first direction and second direction being perpendicular to each other. The GOAs (GOA_L, GOA_R) are disposed in the non-display area and are electrically connected to the multiple scanning lines. The source drive circuit DD is electrically connected to the multiple data lines DATA via a flexible circuit board. The timing controller TCON is electrically connected to the GOAs (GOA_L, GOA_R) and the source drive circuit DD, respectively.

The display panel DP includes an OLED array substrate and an encapsulation layer. The OLED array substrate includes a substrate, a buffer layer disposed on the substrate, an active layer disposed on the buffer layer, a gate insulating layer disposed on the active layer, a first metal layer disposed on the gate insulating layer, an interlayer insulating layer disposed on the first metal layer, a second metal layer disposed on the interlayer insulating layer, a planarization layer disposed on the second metal layer, a first electrode layer disposed on the planarization layer, a pixel definition layer disposed on the first electrode layer, an organic light-emitting layer disposed within an aperture area defined by the pixel definition layer and a second electrode layer disposed on the organic light-emitting layer. The first metal layer includes scanning lines, gate electrodes, etc. The second metal layer includes data lines DATA, source electrodes, drain electrodes, etc. The encapsulation layer is hermetically connected to the OLED array substrate to prevent moisture and oxygen from invading the organic light-emitting layer.

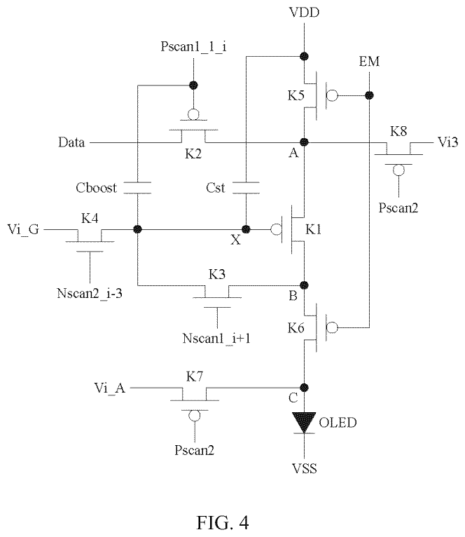

Each pixels PX includes a pixel drive circuit and an OLED (light-emitting device). The pixel drive circuit may be, for example, an 8T2C structure circuit as shown in FIG. 4.

The GOA (GOA_L, GOA_R) includes N gate driver units that are cascaded, with each of the N gate driver units electrically connected to a scanning line. Under the control of the timing controller TCON, the gate driver units sequentially output gate drive signals to scan each row of pixels PX in the display area AA. The source drive circuit DD generates and outputs data signals based on image data under the control of the timing controller TCON. The timing controller TCON is configured to receive and process externally input image data and timing signals, generate control signals and transmit image data to the source drive circuit DD. The power management chip supplies operating voltages to various components of the display device, the operating voltages include a second power supply voltage VSS for the cathode of the OLED, a first power supply voltage VDD for the first power supply voltage line, and gate drive voltage VGH/VGL for the GOAs (GOA_L, GOA_R).

The display device shown in FIG. 1 includes a display panel DP. The display panel DP includes two GOAs (GOA_L, GOA_R) and multiple pixels PX. One of the two GOAs (GOA_L, GOA_R) is disposed on a side of the display area AA of the display panel DP, while another of the two GOAs (GOA_L, GOA_R) is disposed on another side of the display area AA. Each GOAs (GOA_L, GOA_R) includes multiple gate drive subcircuits that are cascaded. The GOA (GOA_L, GOA_R) of the display device according to the embodiments of the present application include two drive architecture implementations:

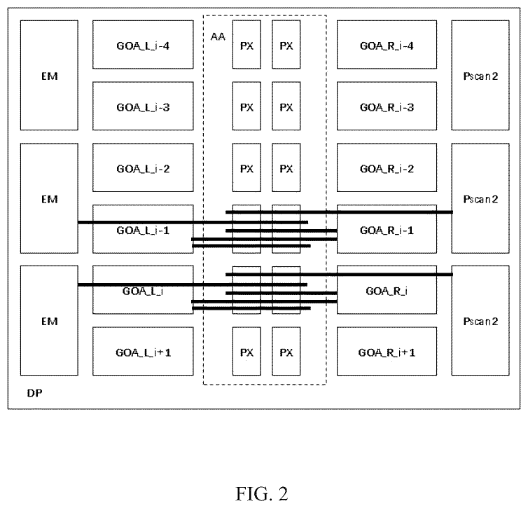

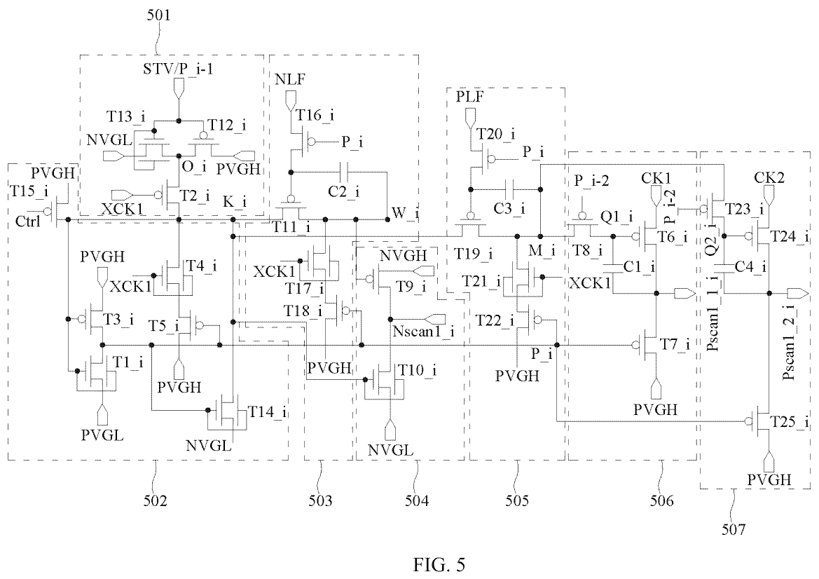

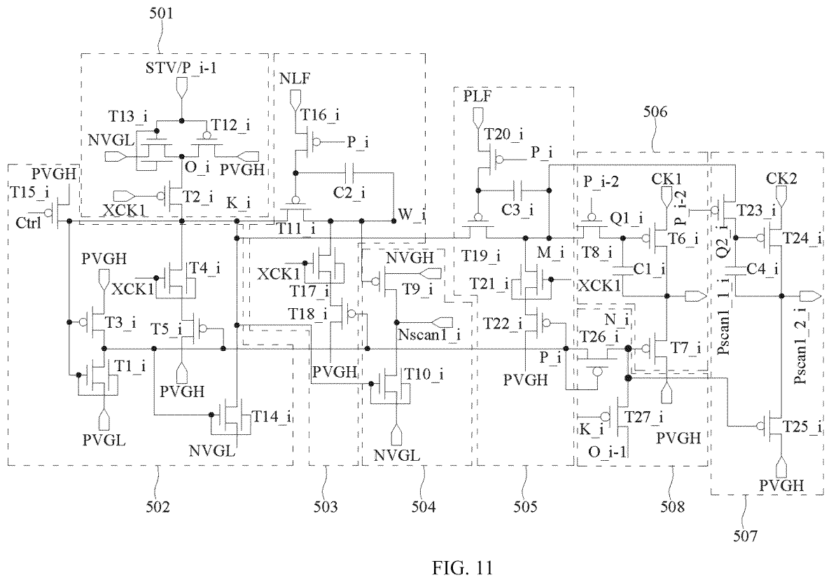

One implementation is a one-to-one drive mode, as shown in FIG. 1, FIG. 2, FIG. 5 and FIG. 11, where a gate drive subcircuit drives pixels PX in a single row. Under this mode, a gate drive subcircuit includes a shift register module 501, a self-stabilizing module 502, a first frequency-division control module 505, a second frequency-division control module 503, a first gate drive signal output module 506 and a third gate drive signal output module 504. The i-th stage gate drive subcircuit GOA_L_i of the GOA GOA_L disposed on a side of the display area AA of the display panel DP is electrically connected to the pixel drive circuit for the pixels PX in the i-th row of the display panel DP. Similarly, the i-th stage gate drive subcircuit GOA_R_i of the GOA GOA_R disposed on another side of the display area AA of the display panel DP is electrically connected to the pixel drive circuit for the pixels PX in the i-th row. Specifically, taking the driving of the pixels PX in the i-th row as an example: output terminals Pscan1_1_i of GOA_L_i and GOA_R_i are electrically connected with each other to drive a transistor K2 in the pixel drive circuit for the pixels PX in the i-th row, achieving bilateral drive, an output terminal Nscan1_i of GOA_L_i of the GOA GOA_L drives a transistor K3 in the pixel drive circuit for the pixels PX in the i-th row, an output terminal Nscan2_i of GOA_R_i of the GOA GOA_R drives a transistor K4 in the pixel drive circuit for the pixels PX in the i-th row, a light-emitting control signal output terminal EM of a light-emitting control module drives transistors K5 and K6 in the pixel drive circuit for the pixels PX in the i-th row, and a scan control signal output terminal Pscan2 of a scan control module drives transistors K7 and K8 in the pixel drive circuit for the pixels PX in the i-th row, where i is a positive integer.

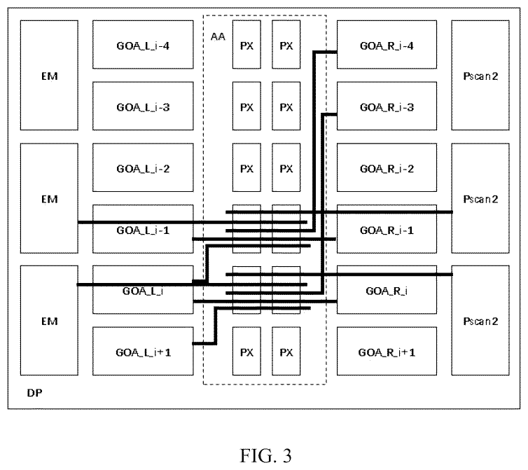

Another implementation is a one-to-two drive mode, as shown in FIG. 1, FIG. 3, FIG. 5 and FIG. 11, where a gate driver subcircuit drives pixels PX in two rows. Under this mode, a gate drive subcircuit includes a shift register module 501, a self-stabilizing module 502, a first frequency-division control module 505, a second frequency-division control module 503, a first gate drive signal output module 506, a second gate drive signal output module 507 and a third gate drive signal output module 504. Each of the i-th stage gate drive subcircuit GOA_L_i of the GOA GOA_L located on a side of the display area AA of the display panel DP and the i-th stage gate drive subcircuit GOA_R_i of the GOA GOA_R located on another side of the display area AA of the display panel DP is electrically connected to the pixel drive circuit for pixels PX in two rows. Specifically, taking the driving of the pixels PX in the i-th row as an example: output terminals Pscan1_1_i of GOA_L_i and GOA_R_i are electrically connected with each other to drive a transistor K2 in the pixel drive circuit for the pixels PX in the i-th row, achieving bilateral drive, an output terminal Nscan1_(i+1) of the (i+1)-th stage gate drive subcircuit GOA_L_(i+1) of the GOA GOA_L drives a transistor K3 in the pixel drive circuit for the pixels PX in the i-th row, an output terminal Nscan2_(i−3) of the (i−3)-th stage gate drive subcircuit GOA_R_(i−3) of the GOA GOA_R drives a transistor K4 in the pixel drive circuit for the pixels PX in the i-th row, an light-emitting control signal output terminal EM of a light-emitting control module drives transistors K5 and K6 in the pixel drive circuit for the pixels PX in the i-th row, and a scan control signal output terminal Pscan2 of a scan control module drives transistors K7 and K8 in the pixel drive circuit for the pixels PX in the i-th row. In this architecture, the falling edges of the start signals STV for the respective gate drive subcircuits on the left and right sides are aligned.

Some embodiments of the present application are applicable to the pixel drive circuit with 8T2C structure for the pixel PX. As shown in FIG. 4, the pixel PX includes a light-emitting device OLED, eight transistors (K1, K2, K3, K4, K5, K6, K7, K8), two capacitors (Cst, Cboost) and multiple gate drive signal input terminals (Pscan1, Pscan2, Nscan1, Nscan2). Specifically, a gate of the transistor K1 is electrically connected to a node X, one of a source and drain of the transistor K1 is electrically connected to a node A, while another of the source and drain of the transistor K1 is electrically connected to a node B. A gate of the transistor K2 is electrically connected to a first gate drive signal input terminal Pscan1_1_i, one of a source and drain of the transistor K2 is electrically connected to a data signal input terminal Data, while another of the source and drain of the transistor K2 is electrically connected to the node A. A gate of the transistor K3 is electrically connected to a third gate drive signal input terminal Nscan1_(i+1), one of a source and drain of the transistor K3 is electrically connected to the node X, while another of the source and drain of the transistor K3 is electrically connected to the node B. A gate of the transistor K4 is electrically connected to a gate drive signal input terminal Nscan2_(i−3), one of a source and drain of the transistor K4 is electrically connected to a first reset signal input terminal Vi_G, while another of the source and drain of the transistor K4 is electrically connected to the node X. A gate of the transistor K5 is electrically connected to a light-emitting control signal output terminal EM, one of a source and drain of the transistor K5 is electrically connected to a high-level power supply input terminal VDD, while another of the source and drain of the transistor K5 is electrically connected to the node A. A gate of the transistor K6 is electrically connected to the light-emitting control signal output terminal EM, one of a source and drain of the transistor K6 is electrically connected to the node B, while another of the source and drain of the transistor K6 is electrically connected to an anode of the light-emitting device OLED. A gate of the transistor K7 is electrically connected to a gate drive signal input terminal Pscan2, one of a source and drain of the transistor K7 is electrically connected to a second reset signal input terminal Vi_A, while another of the source and drain of the transistor K7 is electrically connected to the anode of the light-emitting device OLED. A gate of the transistor K8 is electrically connected to the gate drive signal input terminal Pscan2, one of a source and drain of the transistor K8 is electrically connected to a third reset signal input terminal Vi3, while another of the source and drain of the transistor K8 is electrically connected to the node A. A plate of the capacitor Cst is electrically connected to the high-level power supply input terminal VDD, while another plate of the capacitor Cst is electrically connected to the node X. A plate of the capacitor Cboost is electrically connected to the first gate drive signal input terminal Pscan1_1_i, while another plate of the capacitor Cboost is electrically connected to the node X. A cathode of the light-emitting device OLED is electrically connected to a low-level power supply input terminal VSS.

In this pixel drive circuit for the pixel PX, the first gate drive signal input terminal Pscan1_1_i and the third gate drive signal input terminal Nscan1_(i+1) are relatively close to each other, and a slight short circuit between them may occur when impurity particles are present within the production line. This slight short circuit can cause mutual interference between the two signals from the two signal terminals, particularly during the no active signal input phases of the first gate drive signal Pscan1_1_i and the second gate drive signal Pscan1_2_i, the first gate drive signal Pscan1_1_i and the second gate drive signal Pscan1_2_i are more susceptible to an influence of a third gate drive signal Nscan1 being a low-level output. Simulation results show that the first gate drive signal Pscan1_1_i and the second gate drive signal Pscan1_2_i vary based on the impedance (0.1MΩ~5MΩ) between the two signal terminals, causing a loss in the yield of the display panel DP.

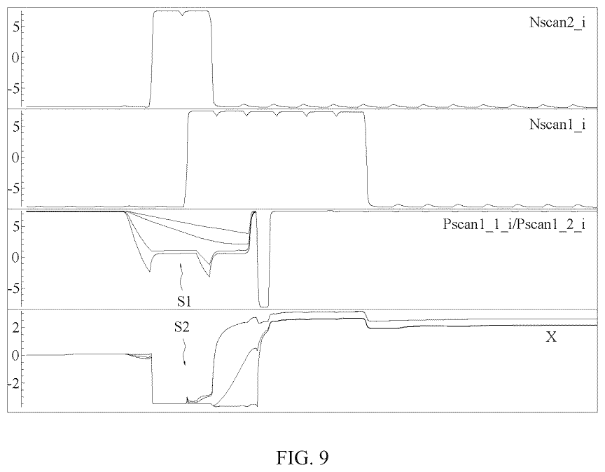

The first gate drive signal input terminal Pscan1_1_i may only short-circuit with the third gate drive signal input terminal Nscan1_(i+1) of the same stage. When the third transistor T3_i is turned off, the third gate drive signal output terminal Nscan1_i is at a low potential NVGL, and the potential of the first gate drive signal output terminal Pscan1_1_i is pulled low. When the third transistor T3_i is turned on, the third gate drive signal Nscan1 is at a high potential NVGH, and the potential of the first gate drive signal output terminal Pscan1_1_i is pulled high. Simulation analysis shows that when the short-circuit resistance Rs ranges from 0.1 MΩ to 10 MΩ, under test conditions of 60 nits brightness and gray scale level L64, the potential difference at the node X in the pixel circuit for the pixel is approximately 20 mV. As shown in FIG. 9, at S1, the high-level waveforms of the first gate drive signal Pscan1_1_i and the second gate drive signal Pscan1_2_i are pulled down due to the influence from the third gate drive signal Nscan1 being a low-level signal.

According to some embodiments of the present application, the GOA (GOA_L, GOA_R) of the display device with the one-to-two drive mode will be illustrated as an example in the following.

Regarding the aforementioned technical issues, the present application proposes two improvement approaches: the first improvement approach involves adjusting the pulse widths of the start signals for the GOA (GOA_L, GOA_R), while the second improvement approach involves improving the circuit structure of the gate drive subcircuit.

The first improvement approach of the present application improves the no active signal input state of the first gate drive signal Pscan1_1_i and the second gate drive signal Pscan1_2_i by setting start signals with different pulse widths.

According to some embodiments of this improvement approach, the display device includes a display panel DP. The display panel DP includes a first GOA GOA_L, a second GOA GOA_R and a plurality of pixels PX. The first GOA GOA_L is disposed on a first side of the display area AA of the display panel DP and includes multiple first gate drive subcircuits that are cascaded. The second GOA GOA_R is positioned on a second side of the display area AA and includes multiple second gate drive subcircuits that are cascaded. Each GOAs (the first GOA GOA_L and the second GOA GOA_R) includes multiple gate drive subcircuits that are cascaded, where each gate drive subcircuits drives pixels PX in two rows.

Each gate driver subcircuit outputs a third gate drive signal Nscan1, a first gate drive signal Pscan1_1_i and a second gate drive signal Pscan1_2_i. The first gate drive signal Pscan1_1_i is supplied to pixels PX in a row, the second gate drive signal Pscan1_2_i is supplied to pixels PX in another row adjacent to the row, while the third gate drive signal Nscan1 is simultaneously supplied to the pixels PX in the two rows. In the display panel DP, if the GOA (GOA_L, GOA_R) has a start signal STV with a pulse width of YH, where Y is a positive integer, then the duration of the no active signal input time period of each of the first gate drive signal Pscan1_1_i and second gate drive signal Pscan1_2_i generated by the gate drive subcircuit is (Y−2j)H. The no active signal input time period refers to a time period during which the first gate drive signal Pscan1_1_i and the second gate drive signal Pscan1_2_i remain at a constant level due to the absence of active signal input.

In the embodiments, the first gate drive signal output module 506 of the i-th stage gate drive subcircuit (GOA_L_i, GOA_R_i) in the multiple gate drive subcircuits includes a sixth transistor T6_i and an eighth transistor T8_i. A gate of the eighth transistor T8_i is electrically connected to a node P_(i−j) in the (i−j)-th stage gate drive subcircuit (GOA_L_(i−j), GOA_R_(i−j)), one of a source and drain of the eighth transistor T8_i is electrically connected to a node M_i, while another of the source and drain of the eighth transistor T8_i is electrically connected to a node Q1_i. The node Q1_i is a node on a line between the sixth transistor T6_i and the eighth transistor T8_i in the first gate drive signal output module 506, the node M_i is a node on a line connecting the first frequency-division control module 505 to the first gate drive signal output module 506 and the second gate drive signal output module 507, and the node P_(i−j) is the node on a line connecting the first frequency-division control module 505 to the first gate drive signal output module 506 and the second gate drive signal output module 507 within the (i−j)-th stage gate drive subcircuit (GOA_L_(i−j), GOA_R_(i−j)), where j is a positive integer.

The second gate drive signal output module 507 of the i-th stage gate drive subcircuit (GOA_L_i, GOA_R_i) in the multiple gate drive subcircuits includes a twenty-third transistor T23_i and a twenty-fourth transistor T24_i. A gate of the twenty-third transistor T23_i is electrically connected to the node P_(i−j) in the (i−j)-th stage gate drive subcircuit (GOA_L_(i−j), GOA_R_(i−j)), one of a source and drain of the twenty-third transistor T23_i is electrically connected to the node M_i, while another of the source and drain of the twenty-third transistor T23_i is electrically connected to a node Q2_i. The node Q2_i is a node on a line between the twenty-fourth transistor T24_i and the twenty-third transistor T23_i in the second gate drive signal output module 507.

A signal transmitted by the node M_i of the i-th stage gate drive subcircuit GOA_L_i in the first GOA GOA_L is inverse to a signal transmitted by the node P_i. That is, when the signal transmitted by the node M_i is at a high level, the signal transmitted by node P_i is at a low level, and when the signal transmitted by the node M_i is at a low level, the signal transmitted by node P_i is at a high level. A pulse width of the signal transmitted by the node P_i of the i-th stage gate drive subcircuit GOA_L_i in the first GOA GOA_L is Y which is equal to 2jH, where H represents a horizontal scan time unit, ensuring that (Y−2j)H=(2j−2j)H=0H. Consequently, a duration of the no active signal input time period of the first gate drive signal Pscan1_1_i and the second gate drive signal Pscan1_2_i generated by the corresponding gate drive subcircuit is 0. The pulse width of the signal transmitted at the node P_i of the i-th stage gate drive subcircuit GOA_R_i in the second GOA GOA_R is greater than 2jH, where the node P_i is a node on another line connecting the first frequency-division control module 505 to the first gate drive signal output module 506 and the second gate drive signal output module 507.

The pulse width of the signal transmitted at the node P_i of the i-th stage gate drive subcircuit GOA_R_i in the second GOA GOA_R is greater than 2jH, rather than equal to 2jH, because the second GOA GOA_R needs to implement specific functions of the display panel (e.g., variable refresh rate (VRR) function). Therefore, in the embodiments, the pulse width of the signal transmitted at the node P_i of the i-th stage gate drive subcircuit GOA_R_i in the second GOA GOA_R is unchanged. Instead, the pulse width of the signal transmitted at the node P_i of the i-th stage gate drive subcircuit GOA_L_i in the first GOA GOA_L is reduced to 2jH.

The pulse width of the signal transmitted at the node P_i of the i-th stage gate drive subcircuit GOA_L_i in the first GOA GOA_L is equal to the pulse width of the signal transmitted at the node P_(i−j) of the (i−j)-th stage gate drive subcircuit GOA_L_(i−j) in the first GOA GOA_L, as well as the pulse width of a start signal STV1 of the first GOA GOA_L. The pulse width of the signal transmitted at the node P_i of the i-th stage gate drive subcircuit GOA_R_i in the second GOA GOA_R is equal to the pulse width of the signal transmitted at the node P_(i−j) of the (i−j)-th stage gate drive subcircuit GOA_R_(i−j) in the second GOA GOA_R, as well as the pulse width of a start signal STV2 of the second GOA GOA_R.

The high-level pulse transmitted by the node P_i of the i-th stage gate drive subcircuit GOA_L_i in the first GOA GOA_L does not overlap in time with the high-level pulse transmitted by the node P_(i−j) of the (i−j)-th stage gate drive subcircuit GOA_L_(i−j) in the first GOA GOA_L.

The pulse width of the signal transmitted by the node P_i of the i-th stage gate drive subcircuit GOA_L_i in the first GOA GOA_L is smaller than the pulse width of the signal transmitted by the node P_i of the i-th stage gate drive subcircuit GOA_R_i in the second GOA GOA_R by 8H to 12H.

Specifically, j ranges from 1 to 3, e.g., j may be equal to 1, 2 or 3. The pulse width of the signal transmitted by the node P_i of the i-th stage gate drive subcircuit GOA_L_i in the first GOA GOA_L is within the range of 2H to 6H, while the pulse width of the signal transmitted by the node P_i of the i-th stage gate drive subcircuit GOA_R_i in the second GOA GOA_R is within the range of 10H to 18H.

For example, when j is equal to 2, the pulse width of the signal transmitted at the node P_i of the i-th stage gate drive subcircuit GOA_L_i within the first GOA GOA_L is 4H while the pulse width of the signal transmitted at the node P_i of the i-th stage gate drive subcircuit GOA_R_i in the second GOA GOA_R is 12H or 16H.

Specifically, the pulse width of the start signal STV1 of the first GOA GOA_L is 8H to 12H less than the pulse width of the start signal STV2 of the second GOA GOA_R. The pulse width of the start signal STV1 of the first GOA GOA_L is within the range of 2H to 6H, while the pulse width of the start signal STV2 of the second GOA GOA_R is within the range of 10H to 18H. More specifically, the pulse width of the start signal STV1 of the first GOA GOA_L is set to 4H, while the pulse width of the start signal STV2 of the second GOA GOA_L is set to either 12H or 16H. This arrangement ensures that the duration of the no active signal input time period for the first gate drive signal Pscan1_1_i and the second gate drive signal Pscan1_2_i output by the first GOA GOA_L is 0. In this case, the first gate drive signal Pscan1_1_i and the second gate drive signal Pscan1_2_i output by the second GOA GOA_R still have a certain no active signal input time period.

The above configuration has technical advantages as follows: meeting the timing adjustment requirements for VRR while ensuring a certain overlap between the first gate drive signal Pscan1_1_i, the second gate drive signal Pscan1_2_i and the third gate drive signal Nscan1. This overlap ensures the reset signal Vi-G is fully written to node B of the pixel drive circuit, applying appropriate on bias stress (OBS) to the drive transistor K1 within the pixel drive circuit for the pixel PX. A proper OBS can reduce the threshold voltage drift of the drive transistor K1, thereby significantly improving display hysteresis and enhancing stability and uniformity of the display.

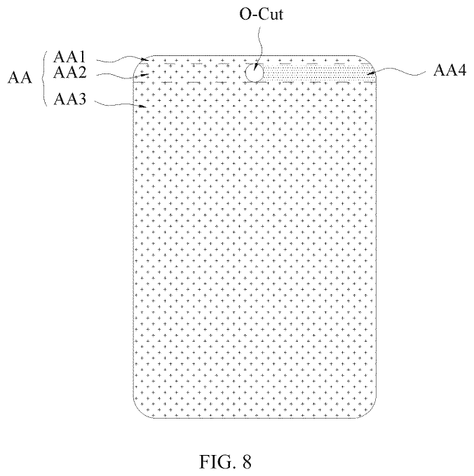

As shown in FIG. 8, the display area AA of the display panel DP includes a first sub-area AA1, a second sub-area AA2, a third sub-area AA3 and a fourth sub-area AA4. The second sub-area AA2 is located on the left side of the under-screen camera opening area O-cut of the display panel DP, while the fourth sub-area AA4 is located on the right side of the under-screen camera opening area O-cut of the display panel DP. The first sub-area AA1 is located above the under-screen camera opening area O-cut, the second sub-area AA2 and the fourth sub-area AA4. The third sub-area AA3 is located below the under-screen camera opening area O-cut, the second sub-area AA2 and the fourth sub-area AA4. For the gate drive subcircuit of the pixels in a horizontal region (the fourth sub-area AA4) corresponding to the right side of the under-screen camera opening area O-cut of display panel DP, the first gate drive signal Pscan1_1_i and the second gate drive signal Pscan1_2_i have a state without active signal input. The fourth sub-area AA4 occupies 1.3% of the display area AA. The combined area of the first sub-area AA1, second sub-area AA2 and third sub-area AA3 occupies 98.7% of the display area AA. Within this 1.3% area, the first gate drive signal output terminal Pscan1_1_i of the first GOA GOA_L is not connected to the first gate drive signal output terminal Pscan1_1_i of the second GOA GOA_R. In the first sub-area AA1 and the third sub-area AA3, the first gate drive signal output terminal Pscan1_1_i of the first GOA GOA_L is connected to the first gate drive signal output terminal Pscan1_1_i of the second GOA GOA_R.

According to some embodiments, the duration of the no active signal input time period for the first gate drive signal Pscan1_1_i and the second gate drive signal Pscan1_2_i output by the first GOA GOA_L is 0. The first gate drive signal Pscan1_1_i and the second gate drive signal Pscan1_2_i output by the second GOA GOA_R still have a certain no active signal input time period. Except for the gate drive subcircuits for the pixels on both sides of the under-display camera of the display panel DP in the display area AA, the first gate drive signal output terminal Pscan1_1_i of the first GOA GOA_L is connected to the first gate drive signal output terminal Pscan1_1_i of the second GOA GOA_R. This arrangement enables the duration of the no active signal input time period for the first gate drive signal Pscan1_1_i and the second gate drive signal Pscan1_2_i of the gate drive subcircuits, which are applied to the pixels in approximately 98.7% of the display area AA (i.e., the sum of the portion of the display area AA of the display panel DP corresponding to a side (e.g., left side) of the under-screen camera opening area, and the portion of the display area AA excluding the portions of the display area AA of the display panel DP corresponding to both sides of the under-screen camera opening area), is 0. The first gate drive signal Pscan1_1_i and the second gate drive signal Pscan1_2_i of the gate drive subcircuits, which are applied for the pixels in only 1.3% of the display area AA (i.e., the portion of the display area AA of the display panel DP corresponding to another side (e.g., the right side) of the under-screen camera opening area), have a certain no active signal input time period. This significantly reduces the risk of abnormal output defects of the first and second gate drive signals Pscan1_1_i and Pscan1_2_i in the prior art, where impurity particles within the production line cause slight short circuits for pixels PX, therefore the first and second gate drive signals Pscan1_1_i and Pscan1_2_i output by the GOAs (GOA_L, GOA_R) become susceptible to interference from other gate drive signals in the state without active signal input, leading to the abnormal outputs defects. The estimated defect rate can be reduced from 0.3% to 0.004%.

Since the lines on the two respective sides of the under-screen camera opening area O-cut in the display panel DP are disconnected, the first gate drive signal Pscan1_1_i and second gate drive signal Pscan1_2_i input to the pixels PX on the right side of the under-screen camera opening area O-cut still have a state without active signal input. However, the area of the right side of the under-screen camera opening area O-cut accounts for only 1.3% of the total area of the display panel DP. Thus, the risk of the first gate drive signal Pscan1_1_i and second gate drive signal Pscan1_2_i operating in the state without active signal input for the entire display area AA is significantly reduced. This prevents the first gate drive signal Pscan1_1_i and Pscan1_2_i from abnormal outputs due to interference from other gate drive signals when they are in the state without active signal input.

The i-th stage gate drive subcircuit of the first GOA GOA_L includes a shift register module 501, a second frequency-division control module 503, a third gate drive signal output module 504, a self-stabilizing module 502, a first frequency-division control module 505, a first gate drive signal output module 506 and a second gate drive signal output module 507, where i is a positive integer.

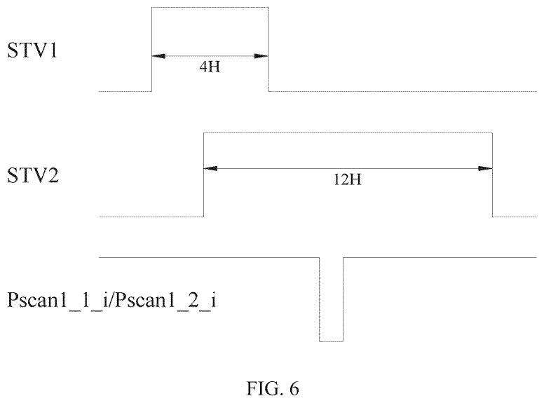

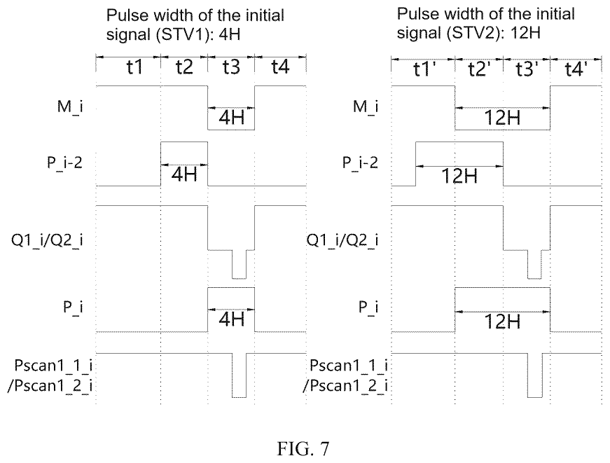

In the i-th stage gate drive subcircuit GOA_L_i of the first GOA GOA_L, as shown in FIG. 6 and FIG. 7, when j is equal to 2 and the pulse width of the start signal STV1 in the first GOA GOA_L is set to 4H, during the first time period (phase t1), the node M_i is at a high level, the node P_(i−2) is at a low level, each of the nodes Q1_i and Q2_i is at a high level, the node P_i is at a low level, and each of the first gate drive signal output terminal Pscan1_1_i of the first gate drive signal output module 506 and the second gate drive signal output terminal Pscan1_2_i of the second gate drive signal output module 507 is at a high level. The node P_(i−2) is a node on a line connecting the first frequency-division control module 505 to the first gate drive signal output module 506 and the second gate drive signal output module 507 in the (i−2)-th stage gate drive subcircuit of the first GOA GOA_L. During the second time period (phase t2) following the first time period (phase t1), the node M_i is at a high level, the node P_(i−2) is at a high level, each of the nodes Q1_i and Q2_i is at a high level, the node P_i is at a low level, and each of the first gate drive signal output Pscan1_1_i and second gate drive signal output Pscan1_2_i is at a high level. During the third time period (phase t3) following the second time period (phase t2), the node M_i is at a low level, the node P_(i−2) is at a low level, each of the nodes Q1_i and Q2_i first is at a low level, then is at a level lower than the low level, and then recovers to the low level, the node P_i is at a high level, each of the first gate drive signal output Pscan1_1_i and the second gate drive signal output Pscan1_2_i first has a high, then is at a low level, and then recovers to the high level. During the fourth time period (phase t4) following the third time period (phase t3), the node M_i is at a high level, the node P_(i−2) is at a low level, each of the nodes Q1_i and Q2_i is at a high level, the node P_i is at a low level, and each of the first gate drive signal output Pscan1_1_i and the second gate drive signal output Pscan1_2_i is at a high level.

The i-th stage gate drive subcircuit of the second GOA GOA_R includes a shift register module 501, a second frequency-division control module 503, a third gate drive signal output module 504, a self-stabilizing module 502, a first frequency-division control module 505, a first gate drive signal output module 506, and a second gate drive signal output module 507, where i is a positive integer.

In the i-th stage gate driver subcircuit GOA_R_i of the second GOA GOA_R, when the pulse width of the start signal STV2 of the second GOA GOA_R is set to 12H, during the first time period (phase t1′), the node M_i is at a high level, the node P_(i−2) first is at a low level, then is at a high level, each of the nodes Q1_i and Q2_i is at a high level, the node P_i is at a low level, and each of the first gate drive signal output terminal Pscan1_1_i of the first gate drive signal output module 506 and the second gate drive signal output terminal Pscan1_2_i of the second gate drive signal output module 507 is at a high level. The node P_(i−2) is a node on a line connecting the first frequency-division control module 505 to the first gate drive signal output module 506 and second gate drive signal output module 507 in the (i−2)-th stage gate drive subcircuit of the second GOA GOA_R. During the second time period (phase t2′) following the first time interval (phase t1′), the node M_i is at a low level, the node P_(i−2) is at a high level, each of the nodes Q1_i and Q2_i is at a high level, the node P_i is at a high level, and each of the first gate drive signal output Pscan1_1_i and the second gate drive signal output Pscan1_2_i is at a high level. During the third time period (phase t3′) following the second time period (phase t2′), the node M_i is at a low level, the node P_(i−2) is at a low level, each of the nodes Q1_i and Q2_i first is at a low level, then is at a level lower than the low level, and then recovers to the low level, the node P_i is at a high level, and each of the first gate drive signal output Pscan1_1_i and the second gate drive signal output Pscan1_2_i first is at a high level, then is at a low level, and then recovers to the high level. During the fourth time period (phase t4′) following the third time period (phase t3′), the node M_i is at a high level, the node P_(i−2) is at a low level, each of the nodes Q1_i and Q2_i is at a high level, the node P_i is at a low level, and each of the first gate drive signal output Pscan1_1_i and the second gate drive signal output Pscan1_2_i is at a high level.

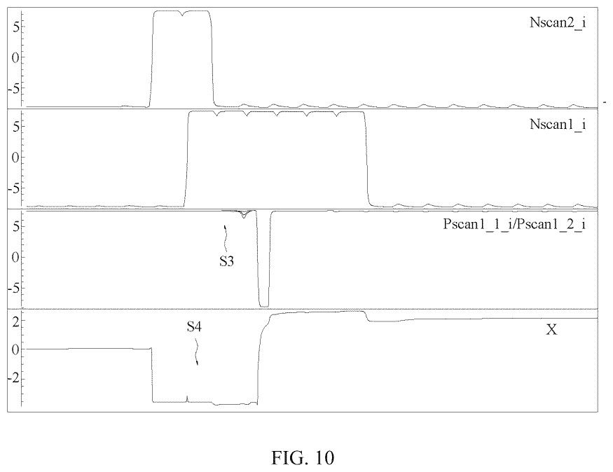

By comparing FIG. 9 with FIG. 10, it can be seen that when slight short circuits occurs in the pixel drive circuits for the pixels X of the display panel DP, after implementing some embodiments, by setting the pulse width of the start signal STV1 of the first GOA GOA_L to 4H, as shown in FIG. 9, the waveforms of the first gate drive signal Pscan1_1_i and the second gate drive signal Pscan1_2_i output by the gate drive subcircuit for the pixels on the right of the under-screen camera opening area O-cut of the display panel DP are pulled low (as indicated at S1 in FIG. 9) due to the short circuit between the gate drive signal input terminals for the pixels PX (under conditions of different impedances, i.e., Rs is equal to 10MΩ, 5MΩ, 1MΩ or 0.5MΩ), causing abnormal potential at the node X in the pixel drive circuit for the pixels (as indicated at S2 in FIG. 9). As shown in FIG. 10, the first gate drive signal Pscan1_1_i and the second gate drive signal Pscan1_2_i output by other gate drive subcircuits for the pixels except the ones on the right side of the under-screen camera opening area O-cut of the display panel DP are not pulled down (as indicated at S3 in FIG. 10) due to the short circuit, and the potential at the node X in the pixel drive circuit for the pixels is not abnormal (as shown at S4 in FIG. 10). This demonstrates that the display device implementing the first improvement approach of the present application can resist dark line defects caused by slight short circuits with impedance above 0.5 MΩ.

The display device of the embodiments includes a display panel DP. The display panel DP includes a first GOA GOA_L, a second GOA GOA_R and multiple pixels PX. Each of the first GOA GOA_L and the second GOA GOA_R includes multiple gate drive subcircuits that are cascaded. As shown in FIG. 5, the i-th stage gate drive subcircuit of the multiple gate drive subcircuits includes a first transistor T1_i, a second transistor T2_i, a third transistor T3_i, a fourth transistor T4_i, a fifth transistor T5_i, a sixth transistor T6_i, a seventh transistor T7_i, an eighth transistor T8_i, a ninth transistor T9_i, a tenth transistor T10_i, a eleventh transistor T11_i, a twelfth transistor T12_i, a thirteenth transistor T13_i, a fourteenth transistor T14_i, a fifteenth transistor T15_i, a sixteenth transistor T16_i, a seventeenth transistor T17_i, an eighteenth transistor T18_i, a nineteenth transistor T19_i, a twentieth transistor T20_i, a twenty-first transistor T21_i, a twenty-second transistor T22_i, a twenty-third transistor T23_i, a twenty-fourth transistor T24_i, a twenty-fifth transistor T25_i, a first capacitor C1_i, a second capacitor C2_i, a third capacitor C3_i, and a fourth capacitor C4_i. Here, i is a positive integer not greater than N.

Each of the first transistor T1_i, the fourth transistor T4_i, the tenth transistor T10_i, the thirteenth transistor T13_i, the fourteenth transistor T14_i, the seventeenth transistor T17_i and the twenty-first transistor T21_i is a N-type transistor and is a dual-gate transistor with two gates of each transistor electrically connected. Each of the second transistor T2_i, the third transistor T3_i, the fifth transistor T5_i, the sixth transistor T6_i, the seventh transistor T7_i, the eighth transistor T8_i, the ninth transistor T9_i, the eleventh transistor T11_i, the twelfth transistor T12_i, the fifteenth transistor T15_i, the sixteenth transistor T16_i, the eighteenth transistor T18_i, the nineteenth transistor T19_i, the twentieth transistor T20_i, the twenty-second transistor T22_i, the twenty-third transistor T23_i, the twenty-fourth transistor T24_i and the twenty-fifth transistor T25_i is a P-type transistor and is a single-gate transistor.

One of the source and drain of the first transistor T1_i is electrically connected to the first low-level signal input terminal PVGL. The first transistor T1_i has two gates electrically connected with each other. The gates of the first transistor T1_i are electrically connected to the node K_i, and another of the source and drain of the first transistor T1_i is electrically connected to the node P_i. The gate of the second transistor T2_i is electrically connected to the third clock signal input terminal XCK1, one of the source and drain of the second transistor T2_i is electrically connected to the node O_i, and another of the source and drain of the second transistor T2_i is electrically connected to the node K_i. The gate of the third transistor T3_i is electrically connected to the node K_i, one of the source and drain terminals of the third transistor T3_i is electrically connected to the first high-level signal input terminal PVGH, and another of the source and drain of the third transistor T3_i is electrically connected to the node P_i. The fourth transistor T4_i has two gates electrically connected with each other. The gates of the fourth transistor T4_i are electrically connected to the third clock signal input terminal XCK1, and one of the source and drain of the fourth transistor T4_i is electrically connected to the node K_i. The gate of the fifth transistor T5_i is electrically connected to the node P_i, one of the source and drain of the fifth transistor T5_i is electrically connected to the first high-level signal input terminal PVGH, and another of the source and drain of the fifth transistor T5_i is electrically connected to another of the source and drain of the fourth transistor T4_i.

The gate of the sixth transistor T6_i is electrically connected to the node Q1_i, one of the source and drain of the sixth transistor T6_i is electrically connected to the first clock signal input terminal CK1, and another of the source and drain of the sixth transistor T6_i is electrically connected to the first gate drive signal output terminal Pscan1_1_i. The gate of the seventh transistor T7_i is electrically connected to the node P_i, one of the source and drain of the seventh transistor T7_i is electrically connected to the first high-level signal input terminal PVGH, and another of the source and drain of the seventh transistor T7_i is electrically connected to the first gate drive signal output terminal Pscan1_1_i. The gate of the eighth transistor T8_i is electrically connected to the node P_(i−j) in the (i−j)-th stage gate drive subcircuit, one of the source and drain of the eighth transistor T8_i is electrically connected to the node M_i, and another of the source and drain of the eighth transistor T8_i is electrically connected to the node Q1_i.

The gate of the ninth transistor T9_i is electrically connected to the node W_i, one of the source and drain of the ninth transistor T9_i is electrically connected to the second high-level signal input terminal NVGH, and another of the source and drain of the ninth transistor T9_i is electrically connected to the third gate drive signal output terminal Nscan1_i. The gate of the tenth transistor T10_i is electrically connected to the node K_i, one of the source and drain of the tenth transistor T10_i is electrically connected to the second low-level signal input terminal NVGL, and another of the source and drain of the tenth transistor T10_i is electrically connected to the third gate drive signal output terminal Nscan1_i. The tenth transistor T10_i has two gates electrically connected with each other.

One of the source and drain of the eleventh transistor T11_i is electrically connected to the node K_i, while another of the source and drain of the eleventh transistor T11_i is electrically connected to the node W_i. The gate of the twelfth transistor T12_i is electrically connected to the start signal input terminal STV, one of the source and drain of the twelfth transistor T12_i is electrically connected to the first high-level signal input terminal PVGH, and another of the source and drain of the twelfth transistor T12_i is electrically connected to the node O_i. The gate of the thirteenth transistor T13_i is electrically connected to the start signal input terminal STV, one of the source and drain of the thirteenth transistor T13_i is electrically connected to the second low-level signal input terminal NVGL, and another of the source and drain of the thirteenth transistor T13_i is electrically connected to the node O_i. The gate of the fourteenth transistor T14_i is electrically connected to the node P_i. The fourteenth transistor T14_i has two gates electrically connected with each other. One of the source and drain of the fourteenth transistor T14_i is electrically connected to the second low-level signal input terminal NVGL, while another of the source and drain of the fourteenth transistor T14_i is electrically connected to the node K_i. The gate of the fifteenth transistor T15_i is electrically connected to the control signal input terminal Ctrl, one of the source and drain of the fifteenth transistor T15_i is electrically connected to the first high-level signal input terminal PVGH, and another of the source and drain of the fifteenth transistor T15_i is electrically connected to the node K_i.

The gate of the sixteenth transistor T16_i is electrically connected to the node P_i, one of the source and drain of the sixteenth transistor T16_i is electrically connected to the first zone-based frequency-division control signal input terminal NLF, and another of the source and drain of the sixteenth transistor T16_i is electrically connected to the gate of the eleventh transistor T11_i. The gate of the seventeenth transistor T17_i is electrically connected to the third clock signal input terminal XCK1. The seventeenth transistor T17_i has two gates electrically connected with each other. One of the source and drain of the seventeenth transistor T17_i is electrically connected to the node W_i. The gate of the eighteenth transistor T18_i is electrically connected to the node P_i, one of the source and drain of the eighteenth transistor T18_i is electrically connected to the first high-level signal input PVGH, and another of the source and drain of the eighteenth transistor T18_i is electrically connected to another of the source and drain of the seventeenth transistor T17_i. One of the source and drain of the nineteenth transistor T19_i is electrically connected to the node K_i, while another of the source and drain of the nineteenth transistor T19_i is electrically connected to the node M_i. The gate of the twentieth transistor T20_i is electrically connected to node P_i. One of the source and drain of the twentieth transistor T20_i is electrically connected to the second zone-based frequency-division control signal input terminal PLF, while another of the source and drain of the twentieth transistor T20_i is electrically connected to the gate of the nineteenth transistor T19_i.

The gate of the twenty-first transistor T21_i is electrically connected to the third clock signal input terminal XCK1. The twenty-first transistor T21_i has two gates electrically connected with each other. One of the source and drain of the twenty-first transistor T21_i is electrically connected to the node M_i. The gate of the twenty-second transistor T22_i is electrically connected to the node P_i, one of the source and drain of the twenty-second transistor T22_i is electrically connected to the first high-level signal input terminal PVGH, and another of the source and drain of the twenty-second transistor T22_i is electrically connected to another of the source and drain of the twenty-first transistor T21_i. The gate of the twenty-third transistor T23_i is electrically connected to the node P_(i−j) in the (i−j)-th stage gate driver subcircuit, one of the source and drain of the twenty-third transistor T23_i is electrically connected to the node M_i, and another of the source and drain of the twenty-third transistor T23_i is electrically connected to the node Q2_i. The gate of the twenty-fourth transistor T24_i is electrically connected to the node Q2_i, one of the source and drain of the twenty-fourth transistor T24_i is electrically connected to the second clock signal CK2, and another of the source and drain of the twenty-fourth transistor T24_i is electrically connected to the second gate drive signal output terminal Pscan1_2_i. The gate of the twenty-fifth transistor T25_i is electrically connected to the node P_i, one of the source and drain of the twenty-fifth transistor T25_i is electrically connected to the first high-level signal input terminal PVGH, and another of the source and drain of the twenty-fifth transistor T25_i is electrically connected to the second gate drive signal output terminal Pscan1_2_i.

A plate of the first capacitor C1_i is electrically connected to the node Q1_i, while another plate of the first capacitor C1_i is electrically connected to the first gate drive signal output terminal Pscan1_1_i. A plate of the second capacitor C2_i is electrically connected to the node W_i, while another plate of the second capacitor C2_i is electrically connected to the gate of the eleventh transistor T11_i. A plate of the third capacitor C3_i is electrically connected to the node M_i, while another plate of the third capacitor C3_i is electrically connected to the gate of the nineteenth transistor T19_i. A plate of the fourth capacitor C4_i is electrically connected to the node Q2_i, while another plate of the fourth capacitor C4_i is electrically connected to the second gate drive signal output terminal Pscan1_2_i.

The second improvement approach of the present application addresses the issue of the first gate drive signal Pscan1_1_i and the second gate drive signal Pscan1_2_i lacking active signal inputs from a circuit perspective.

In the i-th stage gate drive subcircuit, the first gate drive signal Pscan1_1_i and the second gate drive signal Pscan1_2_i have no active signal inputs because the signal at the node P_(i−j) of the (i−j)-th stage gate drive subcircuit turns off the eighth transistor T8_i, interrupting the potential linkage between the node M_i and the node Q1_i, thereby maintaining the node Q1_i at a high level. Simultaneously, when the signal at the node P_i is at a high level, the seventh transistor T7_i cannot be turned on. Consequently, the first gate drive signal Pscan1_1_i and the second gate drive signal Pscan1_2_i cannot receive high-level signal (active signal) inputs.

As shown in FIG. 11, the embodiments of this improvement approach add a control module 508 to the i-th stage gate drive subcircuit in FIG. 5, ensuring that during the no active signal input time period, an active high-level signal can be input to the first gate drive signal output terminal Pscan1_1_i.

The display device according to the embodiments of the present application includes a display panel DP. The display panel DP includes two GOAs (GOA_L, GOA_R) and multiple pixels PX. One of the two GOAs (GOA_L, GOA_R) is disposed on a side of the display area AA of the display panel DP, while another of the two GOAs (GOA_L, GOA_R) is disposed on another side of the display area AA. Each GOAs (GOA_L, GOA_R) includes multiple gate drive subcircuits that are cascaded. Each of the i-th stage gate drive subcircuit of the GOA GOA_L disposed on the side of the display area AA and the i-th stage gate drive subcircuit of the GOA GOA_R disposed on the another side of the display area AA is electrically connected to the pixels PX in two rows, where i is a positive integer.

The i-th stage gate drive subcircuit of the GOA (GOA_L, GOA_R) disposed on at least one side of the display area AA of the display panel DP includes the transistors T1_i to T27_i and the capacitors C1_i to C4_i. Specifically, the i-th stage gate drive subcircuit includes: the first gate drive signal output module 506, which includes the sixth transistor T6_i, the seventh transistor T7_i, the eighth transistor T8_i and the first capacitor C1_i; the second gate drive signal output module 507, which includes the twenty-third transistor T23_i, the twenty-fourth transistor T24_i, the twenty-fifth transistor T25_i and the fourth capacitor C4_i; and the control module 508, which includes the twenty-sixth transistor T26_i and the twenty-seventh transistor T27_i.

The gate of the seventh transistor T7_i is electrically connected to the node N_i, one of the source and drain of the seventh transistor T7_i is electrically connected to the first high-level signal input terminal PVGH, and another of the source and drain of the seventh transistor T7_i is electrically connected to the first gate drive signal output terminal Pscan1_1_i. The node N_i is a node on a line connecting the control module 508 to the first gate drive signal output module 506 and the second gate drive signal output module 507. The gate of the twenty-fifth transistor T25_i is electrically connected to the node N_i, one of the source and drain of the twenty-fifth transistor T25_i is electrically connected to the first high-level signal input terminal PVGH, and another of the source and drain of the twenty-fifth transistor T25_i is electrically connected to the second gate drive signal output terminal Pscan1_2_i. The gate of the twenty-sixth transistor T26_i is electrically connected to the node P_i, one of the source and drain of the twenty-sixth transistor T26_i is electrically connected to the node P_i, and another of the source and drain of the twenty-sixth transistor T26_i is electrically connected to the node N_i. The gate of the twenty-seventh transistor T27_i is electrically connected to the node K_i, one of the source and drain of the twenty-seventh transistor T27_i is electrically connected to the node N_i, and another of the source and drain of the twenty-seventh transistor T27_i is electrically connected to the node O_(i−k). The node K_i is a node on a line between the self-stabilizing module 502 and the first frequency-division control module 505, the node P_i is a node on another line between the self-stabilizing module 502 and the first frequency-division control module 505, and the node O_(i−k) is a node on a line between the twelfth transistor T12_i and the thirteenth transistor T13_i in the self-stabilizing module 502 of the (i−k)-th stage gate drive subcircuit, where k is a positive integer, for example, k may be equal to 1.

The i-th stage gate drive subcircuit further includes: the shift register module 501, which includes the second transistor T2_i, the twelfth transistor T12_i and the thirteenth transistor T13_i; the self-stabilizing module 502, which includes the first transistor T1_i, the third transistor T3_i, the fourth transistor T4_i, the fifth transistor T5_i, the fourteenth transistor T14_i and the fifteenth transistor T15_i; the second frequency-division control module 503, which includes the eleventh transistor T11_i, the sixteenth transistor T16_i, the seventeenth transistor T17_i, the eighteenth transistor T18_i and the second capacitor C2_i; the third gate drive signal output module 504, which includes the ninth transistor T9_i and the tenth transistor T10_i; and the first frequency-division control module 505, which includes the nineteenth transistor T19_i, the twentieth transistor T20_i, the twenty-first transistor T21_i, the twenty-second transistor T22_i and the third capacitor C3_i.

Each of the first frequency-division control module 505, the self-stabilizing module 502, the first gate drive signal output module 506 and the second gate drive signal output module 507 is electrically connected to the control module 508. The shift register module 501 is electrically connected to the self-stabilizing module 502. Each of the second frequency-division control module 503 and the first frequency-division control module 505 in electrically connected to the shift register module 501 and the self-stabilizing module 502. The third gate drive signal output module 504 is electrically connected to the self-stabilizing module 502 and the second frequency-division control module 503. The second frequency-division control module 503 is electrically connected to the self-stabilizing module 502 and the control module 508. Each of the first gate drive signal output module 506 and the second gate drive signal output module 507 is electrically connected to the control module 508. The control module 508 is electrically connected to the first frequency-division control module 505 and the self-stabilizing module 502.

Each of the twenty-sixth transistor T26_i and the twenty-seventh transistor T27_i in the control module 508 is a P-type transistor. The gate of the twenty-sixth transistor T26_i is electrically connected to the node P_i within the first frequency-division control module 505, one of the source and drain of the twenty-sixth transistor T26_i is electrically connected to the node P_i, and another of the source and drain of the twenty-sixth transistor T26_i is electrically connected to the node N_i. The gate of the twenty-seventh transistor T27_i is electrically connected to the node K_i in the self-stabilizing module 502, the source of the twenty-seventh transistor T27_i is electrically connected to the node O_(i−k) of the (i−k)-th stage gate drive subcircuit, and the drain of the twenty-seventh transistor T27_i is electrically connected to the node N_i. The gate of the seventh transistor T7_i in the first gate drive signal output module 506 is electrically connected to the node N_i, and the gate of the twenty-fifth transistor T25_i in the second gate drive signal output module 507 is electrically connected to the node N_i.

The transistor T26_i is used to block high-level signals transmitted from the node P_i to the node N_i when the node P_i is at a high level. The twenty-seventh transistor T27_i is used to transmit a low-level signal to the node N_i when the node P_i is at a high level, the node K_i is at a low level, and the node O_(i−k) of the (i−k)-th stage gate driver subcircuit is at a low level. The seventh transistor T7_i and the twenty-fifth transistor T25_i are turned on when the node N_i is at a low level and transmit the signals from the first high-level signal input terminal PVGH to the first gate drive signal output terminal Pscan1_1_i and the second gate drive signal output terminal Pscan1_2_i, respectively.

The connection relationships of transistors in this improvement approach corresponding to the transistors in the first improvement approach are identical to those in the first improvement approach.

In conventional gate drive subcircuits, the signal at the node P_(i−j) of the (i−j)-th stage gate drive subcircuit turns off the eighth transistor T8_i, resulting in the first gate drive signal Pscan1_1_i and the second gate drive signal Pscan1_2_i being in a state without active signal input. The embodiment of the second improvement approach fundamentally change this by adding a control module 508 (including the twenty-sixth transistor T26_i and the twenty-seventh transistor T27_i) to extend the duration of the time period during which the seventh transistor T7_i outputs an active high-level signal.

In this example, the gates of the seventh transistor T7_i and the twenty-fifth transistor T25_i are no longer electrically connected to the node P_i, but are electrically connected to the node N_i. The gate of the twenty-seventh transistor T27_i is electrically connected to the node K_i, the source of the twenty-seventh transistor T27_i is electrically connected to the node O_(i−k) of the (i−k)-th stage gate drive subcircuit, and the drain of the twenty-seventh transistor T27_i is electrically connected to the node N_i.

One of the source and drain of the seventh transistor T7_i is electrically connected to the first high-level signal input terminal PVGH, while another of the source and drain of the seventh transistor T7_i is electrically connected to the first gate drive signal output terminal Pscan1_1_i.

One of the source and drain of the twenty-fifth transistor T25_i is electrically connected to the first high-level signal input terminal PVGH, while another of the source and drain of the twenty-fifth transistor T25_i is electrically connected to the second gate drive signal output terminal Pscan1_2_i.

The seventh transistor T7_i is turned on when the node N_i is at a low level and is used to transmit the signal from the first high-level signal input terminal PVGH to the first gate drive signal output terminal Pscan1_1_i. The twenty-fifth transistor T25_i is turned on when the node N_i is at a low level and is used to transmit the signal from the first high-level signal input PVGH to the second gate drive signal output Pscan1_2_i.

The twenty-sixth transistor T26_i is used to blocks high-level signals transmitted from the node P_i to the node N_i when the node P_i is at a high level. The twenty-seventh transistor T27_i is used to transmit low-level signals to the node N_i when the node K_i is at a low level and the node O_(i−k) of the (i−k)-th stage gate drive subcircuit is at a low level.

After adding the twenty-sixth transistor T26_i and the twenty-seventh transistor T27_i, the signal from the original node P_i can be transmitted to the node N_i under the control of the twenty-sixth transistor T26_i. Furthermore, the twenty-sixth transistor T26_i can block the high-level signal from the node P_i. In this circuit structure, the twenty-seventh transistor T27_i is controlled by the node K_i. When the node K_i is at a low level, the twenty-seventh transistor T27_i can transmit the low-level signal from the node O_(i−k) of the (i−k)-th stage gate driver subcircuit to the node N_i. This enables the node N_i to receive a low-level signal during the period when each of the nodes Q1_i and P_(i−j) is at a high level, thereby turning on the seventh transistor T7_i. Simultaneously, this embodiment does not interfere with the normal driving function of the sixth transistor T6_i by the node Q1_i with a low level. Simulation results show that during the time period without active signal input for the original first gate drive signal Pscan1_1_i, by turning on the seventh transistor T7_i with the low-level signal at node N_i, the active high-level signal PVGH is input to the first gate drive signal output terminal Pscan1_1_i, so that the first gate drive signal Pscan1_1_i receives the active signal input and no longer remain in a high level hold state.

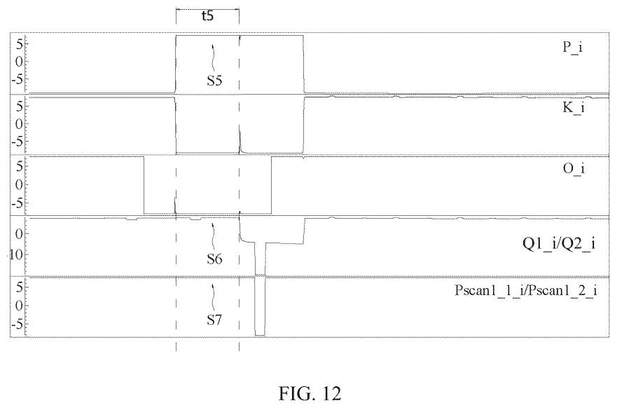

As shown in FIG. 12, prior to applying the second improvement approach of the present application, at stage t5 (t5 has no temporal continuity with the preceding t1 to t4), the node P_i in the gate drive subcircuit of the display device is at a high level (as indicated at S5 in FIG. 12), the node K_i is at a low level, the node O_i is at a low level and each of the nodes Q1_i and Q2_i is at a high level (as shown at S6 in FIG. 12). Each of the first gate drive signal Pscan1_1_i and the second gate drive signal Pscan1_2_i is at a high level but is in a state without active signal input (as shown at S7 in FIG. 12).

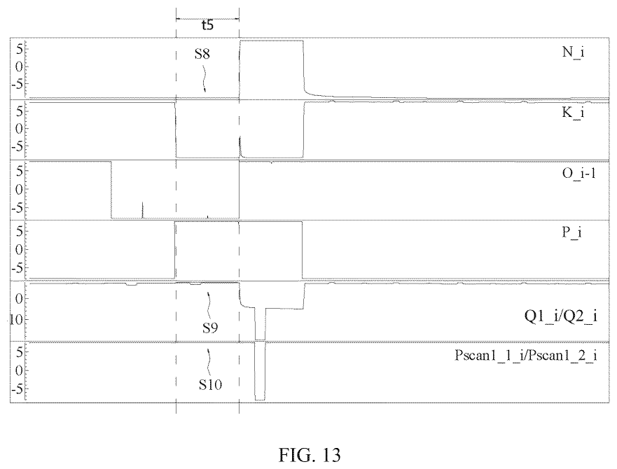

As shown in FIG. 13, after applying the second improvement approach of the present application, at stage t5, the node N_i in the gate drive subcircuit of the display device is at a low level (as shown at S8 in FIG. 13), the node K_i is at a low level, the node O_i is at a low level, the node P_i is at a high level, and each of the nodes Q1_i and Q2_i is at a high level (as shown at S9 in FIG. 13). Each of the first gate drive signal Pscan1_1_i and the second gate drive signal Pscan1_2_i is at a high level and is combined with the PVGH signal, thus being in a state with active signal input (as shown at S10 in FIG. 13).

In the above embodiments, the present application provides solutions to improve the output retention of the gate drive signal from different perspectives. The first improvement approach ensures the active signal input for each of the first gate drive signal Pscan1_1_i and the second gate drive signal Pscan1_2_i across most area of the display panel DP through timing configuration. The second improvement approach ensures the active signal input for the entire output period of each of the first gate drive signal Pscan1_1_i and the second gate drive signal Pscan1_2_i through circuit improvements. These solutions effectively address the issue that the first gate drive signal Pscan1_1_i and the second gate drive signal Pscan1_2_i are susceptible to interference from other gate drive signals during the high level hold state, thereby improving the yield rate of display panel products.

Some embodiments of the present application have been described in detail above. The embodiments are described for illustrative purposes only and are not intended to limit the present application. Many modifications or equivalent substitutions with respect to the embodiments may occur to those of ordinary skill in the art based on the present application and thus shall fall within the scope of the present application as defined by the appended claims.

What is claimed is:

1. A display device comprising a display panel, the display panel comprising:
a first gate driver on array (GOA) disposed on a first side of a display area of the display panel; and
a second GOA disposed on a second side of the display area,
wherein each of the first GOA and the second GOA comprises a plurality of gate drive subcircuits that are cascaded;
an i-th stage gate drive subcircuit of the gate drive subcircuits comprises a first frequency-division control module and a first gate drive signal output module, and has a node M in a line between the first frequency-division control module and the first gate drive signal output module, and a node P in another line between the first frequency-division control module and the first gate drive signal output module, where i is a positive integer, wherein the first gate drive signal output module comprises a sixth transistor and an eighth transistor, wherein a gate of the eighth transistor is electrically connected to the node P in an (i−j)-th stage gate drive subcircuit of the gate drive subcircuits, where j is a positive integer, one of a source of the eighth transistor and a drain of the eighth transistor is electrically connected to the node M, and another of the source and the drain of the eighth transistor is electrically connected to a node Q1 in a line between the sixth transistor and the eighth transistor;
in the i-th stage gate drive subcircuit of the first GOA, a signal transmitted by the node M is inverse to a signal transmitted by the node P, and the signal transmitted by the node P has a pulse width of 2j horizontal scan time units; and
in the i-th stage gate drive subcircuit of the second GOA, a signal transmitted by the node P has a pulse width greater than 2j horizontal scan time units.

2. The display device according to claim 1, wherein a high-level pulse of the signal transmitted by the node P in the i-th stage gate drive subcircuit of the first GOA does not overlap in time with a high-level pulse of a signal transmitted by the node P in the (i−j)-th stage gate drive subcircuit of the first GOA.

3. The display device according to claim 1, wherein the pulse width of the signal transmitted by the node P in the i-th stage gate drive subcircuit of the first GOA is 8 to 12 horizontal scan time units less than the pulse width of the signal transmitted by the node P in the i-th stage gate drive subcircuit of the second GOA.

4. The display device according to claim 1, wherein j ranges from 1 to 3; and
the pulse width of the signal transmitted by the node P in the i-th stage gate drive subcircuit of the second GOA ranges from 10 horizontal scan time units to 18 horizontal scan time units.

5. The display device according to claim 4, wherein j is equal to 2; and
the pulse width of the signal transmitted by the node P in the i-th stage gate drive subcircuit of the second GOA is 12 horizontal scan time units or 16 horizontal scan time units.

6. The display device according to claim 1, wherein a pulse width of a start signal for the first GOA is 8 to 12 horizontal scan time units less than a pulse width of a start signal for the second GOA.

7. The display device according to claim 6, wherein the pulse width of the start signal for the first GOA ranges from 2 horizontal scan time units to 6 horizontal scan time units, and the pulse width of the start signal for the second GOA ranges from 10 horizontal scan time units to 18 horizontal scan time units.

8. The display device according to claim 7, wherein the pulse width of the start signal for the first GOA is 4 horizontal scan time units, and the pulse width of the start signal for the second GOA is 12 horizontal scan time units or 16 horizontal scan time units.

9. The display device according to claim 1, wherein in the i-th stage gate drive subcircuit of the first GOA,
during a first time period, the node M is at a high level, the gate of the eighth transistor is at a low level, the node Q1 is at a high level, the node P is at a low level, and a first gate drive signal output terminal of the first gate drive signal output module is at a high level;
during a second time period after the first time period, the node M is at a high level, the gate of the eighth transistor is at a high level, the node Q1 is at a high level, the node P is at a low level, and the first gate drive signal output terminal is at a high level;
during a third time period after the second time period, the node M is at a low level, the gate of the eighth transistor is at a low level, the node Q1 first is at a low level, then is at a level lower than the low level and then is restored to the low level, the node P is at a high level, and the first gate drive signal output terminal first is at a high level, then is at a low level and then is restored to the high level; and
during a fourth time period after the third time period, the node M is at a high level, the gate of the eighth transistor is at a low level, the node Q1 is at a high level, the node P is at a low level, and the first gate drive signal output terminal is at a high level.

10. The display device according to claim 1, wherein in the i-th stage gate drive subcircuit of the second GOA,
during a first time period, the node M is at a high level, the gate of the eighth transistor first is at a low level and then is at a high level, the node Q1 is at a high level, the node P is at a low level, and a first gate drive signal output terminal of the first gate drive signal output module is at a high level;
during a second time period after the first time period, the node M is at a low level, the gate of the eighth transistor is at a high level, the node Q1 is at a high level, the node P is at a high level, and the first gate drive signal output terminal is at a high level;
during a third time period after the second time period, the node M is at a low level, the gate of the eighth transistor is at a low level, the node Q1 first is at a low level, then is at a level lower than the low level and then is restored to the low level, the node P is at a high level, and the first gate drive signal output terminal first is at a high level, then is at a low level and then is restored to the high level; and
during a fourth time period after the third time period, the node M is at a high level, the gate of the eighth transistor is at a low level, the node Q1 is at a high level, the node P is at a low level, and the first gate drive signal output terminal is at a high level.

11. A display device comprising a display panel, the display panel comprising:
a GOA disposed on at least one side of a display area of the display panel and comprising a plurality of gate drive subcircuits that are cascaded,
wherein an i-th stage gate drive subcircuit of the gate drive subcircuits comprises a self-stabilizing part, a first frequency-division control module, a first gate drive signal output module and a control module, where i is a positive integer,
wherein the first gate drive signal output module comprises a seventh transistor, wherein a gate of the seventh transistor is electrically connected to a node N in a line between the control module and the first gate drive signal output module, one of a source of the seventh transistor and a drain of the seventh transistor is electrically connected to a first high-level signal input terminal, and another of the source and the drain of the seventh transistor is electrically connected to a first gate drive signal output terminal; and
the control module comprises a twenty-sixth transistor and a twenty-seventh transistor, wherein a gate of the twenty-sixth transistor is electrically connected to a node P in a line between the self-stabilizing part and the first frequency-division control module, one of a source of the twenty-sixth transistor and a drain of the twenty-sixth transistor is electrically connected to the node P, and another of the source and the drain of the twenty-sixth transistor is electrically connected to the node N, and wherein a gate of the twenty-seventh transistor is electrically connected to a node K in another line between the self-stabilizing part and the first frequency-division control module, one of a source of the twenty-seventh transistor and a drain of the twenty-seventh transistor is electrically connected to the node N, and another of the source and the drain of the twenty-seventh transistor is electrically connected to a node O in a line between a twelfth transistor and a thirteenth transistor in an (i−k)-th stage gate drive subcircuit of the gate drive subcircuits, where k is a positive integer.

12. The display device according to claim 11, wherein in the i-th stage gate drive subcircuit, the control module is electrically connected to the first frequency-division control module, the self-stabilizing part and the first gate drive signal output module.

13. The display device according to claim 11, wherein the i-th stage gate drive subcircuit further comprises a shift register module, a second frequency-division control module and a third gate drive signal output module; and
in the i-th stage gate drive subcircuit, the shift register module is electrically connected to the self-stabilizing part, each of the second frequency-division control module and the first frequency-division control module is electrically connected to the shift register module and the self-stabilizing part, the second frequency-division control module is electrically connected to the self-stabilizing part, the control module and the third gate drive signal output module, and the third gate drive signal output module is electrically connected to the self-stabilizing part and the second frequency-division control module.

14. The display device according to claim 11, wherein each of the twenty-sixth transistor and the twenty-seventh transistor is a P-type transistor.

15. The display device according to claim 11, wherein in the i-th stage gate drive subcircuit, the twenty-sixth transistor is configured to, when the node P is at a high level, block a high-level signal to be transmitted from the node P to the node N, and the twenty-seventh transistor is configured to, when the node P is at a high level, the node K is at a low level and the node O in the (i−k)-th stage gate drive subcircuit is at a low level, transmit a low-level signal to the node N.

16. The display device according to claim 11, wherein in the i-th stage gate drive subcircuit, the seventh transistor is configured to, when the node N is at a low level, be turned on to transmit a signal from the first high-level signal input terminal to the first gate drive signal output terminal.

17. The display device according to claim 11, wherein in the i-th stage gate drive subcircuit, the first gate drive signal output module further comprises a sixth transistor, an eighth transistor and a first capacitor,
wherein a gate of the sixth transistor is electrically connected to a node Q1 in a line between the sixth transistor and the eighth transistor, one of a source of the sixth transistor and a drain of the sixth transistor is electrically connected to a first clock signal input terminal, and another of the source and the drain of the sixth transistor is electrically connected to the first gate drive signal output terminal;
a gate of the eighth transistor is electrically connected to the node P in an (i−j)-th stage gate drive subcircuit of the gate drive subcircuits, where j is a positive integer, one of a source of the eighth transistor and a drain of the eighth transistor is electrically connected to a node M in a line between the first frequency-division control module and the first gate drive signal output module, and another of the source and the drain of the eighth transistor is electrically connected to the node Q1; and
a plate of the first capacitor is electrically connected to the node Q1, and another plate of the first capacitor is electrically connected to the first gate drive signal output terminal.

18. The display device according to claim 17, wherein in the i-th stage gate drive subcircuit, a signal transmitted by the node M is inverse to a signal transmitted by the node P.

19. The display device according to claim 11, wherein in the i-th stage gate drive subcircuit, the self-stabilizing part comprises a first transistor, a third transistor, a fourth transistor, a fifth transistor, a fourteenth transistor and a fifteenth transistor,
wherein a gate of the first transistor is electrically connected to the node K, one of a source of the first transistor and a drain of the first transistor is electrically connected to a first low-level signal input terminal, and another of the source and the drain of the first transistor is electrically connected to the node P;
a gate of the third transistor is electrically connected to the node K, one of a source of the third transistor and a drain of the third transistor is electrically connected to the first high-level signal input terminal, and another of the source and the drain of the third transistor is electrically connected to the node P;
a gate of the fourth transistor is electrically connected to a third clock signal input terminal, and one of a source of the fourth transistor and a drain of the fourth transistor is electrically connected to the node K;
a gate of the fifth transistor is electrically connected to the node P, one of a source of the fifth transistor and a drain of the fifth transistor is electrically connected to the first high-level signal input terminal, and another of the source and the drain of the fifth transistor is electrically connected to another of the source and the drain of the fourth transistor;
a gate of the fourteenth transistor is electrically connected to the node P, one of a source of the fourteenth transistor and a drain of the fourteenth transistor is electrically connected to a second low-level signal input terminal, and another of the source and the drain of the fourteenth transistor is electrically connected to the node K; and
a gate of the fifteenth transistor is electrically connected to a control signal input terminal, one of a source of the fifteenth transistor and a drain of the fifteenth transistor is electrically connected to the first high-level signal input terminal, and another of the source and the drain of the fifteenth transistor is electrically connected to the node K.

20. The display device according to claim 11, wherein in the i-th stage gate drive subcircuit, the first frequency-division control module comprises a nineteenth transistor, a twentieth transistor, a twenty-first transistor, a twenty-second transistor and a third capacitor,
wherein one of a source of the nineteenth transistor and a drain of the nineteenth transistor is electrically connected to the node K, and another of the source and the drain of the nineteenth transistor is electrically connected to a node M;
a gate of the twentieth transistor is electrically connected to the node P, one of a source of the twentieth transistor and a drain of the twentieth transistor is electrically connected to a second zone-based frequency-division control signal input terminal, and another of the source and the drain of the twentieth transistor is electrically connected to a gate of the nineteenth transistor;
a gate of the twenty-first transistor is electrically connected to a third clock signal input terminal, and one of a source of the twenty-first transistor and a drain of the twenty-first transistor is electrically connected to the node M; and
a gate of the twenty-second transistor is electrically connected to the node P, one of a source of the twenty-second transistor and a drain of the twenty-second transistor is electrically connected to the first high-level signal input terminal, and another of the source and the drain of the twenty-second transistor is electrically connected to another of the source and the drain of the twenty-first transistor.
